(19) United States
(12) Patent Application Publication
(10) Pub. No.: US 2024/0278355 A1
(43) Pub. Date: Aug. 22, 2024

(54) DISPLAY DEVICE AND METHOD OF MANUFACTURING THE SAME

(71) Applicant: Samsung Display Co., Ltd., Yongin-Si (KR)

(72) Inventor: GEUNWOO YUG, Yongin-si (KR)

(21) Appl. No.: 18/418,920

(22) Filed: Jan. 22, 2024

(30) Foreign Application Priority Data
Feb. 22, 2023 (KR) 10-2023-0023690

(51) Int. Cl. B23K 26/38; B23K 101/36; B23K 103/16; H10K 77/10; H10K 102/00

(52) U.S. Cl. CPC B23K 26/38; H10K 77/111; B23K 2101/36; B23K 2103/16; H10K 2102/311

(57) ABSTRACT

A method of manufacturing a display device includes preparing a preliminary foldable module including a window module, a display panel disposed on the window module, a panel protective layer disposed on the display panel, and a support plate disposed on the panel protective layer. Performing a first cutting operation including cutting the support plate with a first laser beam. Detecting, by a laser-sensing part, reflected light that is reflected from a surface of the panel protective layer exposed by cutting the support plate and changing the first laser beam to a second laser beam. Performing a second cutting operation of sequentially cutting the panel protective layer, the display panel, and the window module with the second laser beam.

### CROSS-REFERENCE TO RELATED APPLICATIONS

This application claims priority under 35 U.S.C. § 119 to Korean Patent Application No. 10-2023-0023690, filed on Feb. 22, 2023 in the Korean Intellectual Property Office, the disclosure of which is incorporated by reference in its entirety herein.

### 1. TECHNICAL FIELD

Embodiments of the present disclosure relate to a display device and a method of manufacturing the same, and more particularly, to a display device having less dead space and a method of manufacturing the same.

### 2. DISCUSSION OF RELATED ART

Display devices provide images to users. Display devices are applied to various multimedia devices, such as televisions, mobile phones, tablet computers, game consoles, etc. Recently, various types of flexible display devices, that are foldable or bendable, are being developed.

A flexible display device may include a display module and a window module that are foldable or bendable. The display module provides image information, and the window module permits the image information provided from the display module to be transferred to the outside while protecting the display module from the external environment.

To increase the compactness of the display device, studies on a manufacturing method capable of reducing dead space are being conducted to reduce the size of a bezel of the display device.

### SUMMARY

Embodiments of the present disclosure provides a display device with reduced dead space.

The present disclosure also provides a method of manufacturing a display device capable of reducing dead space.

According to an embodiment of the present disclosure, a method of manufacturing a display device includes preparing a preliminary foldable module including a window module, a display panel disposed on the window module, a panel protective layer disposed on the display panel, and a support plate disposed on the panel protective layer. Performing a first cutting operation including cutting the support plate with a first laser beam. Detecting, by a laser-sensing part, reflected light that is reflected from a surface of the panel protective layer exposed by cutting the support plate and changing the first laser beam to a second laser beam. Performing a second cutting operation of sequentially cutting the panel protective layer, the display panel, and the window module with the second laser beam.

In an embodiment, the first laser beam and the second laser beam may be output from the same laser apparatus. The first and second laser beams may differ from each other only based on laser beam conditions. The preliminary foldable module may be substantially integrally cut.

In an embodiment, the first cutting operation and the second cutting operation may be performed in one cutting stage.

In an embodiment, the reflected light may be not detected by the laser-sensing part in the first cutting operation, and the reflected light may be detected by the laser-sensing part in the second cutting operation.

In an embodiment, an intensity of the first laser beam may be greater than an intensity of the second laser beam.

In an embodiment, the first laser beam may have an output power in a range of about 20 W to about 50 W, and the second laser beam may have an output power in a range of about 1 W to about 20 W.

In an embodiment, the first laser beam and the second laser beam may be each emitted from the support plate towards the panel protective layer.

In an embodiment, the support plate may include a carbon fiber reinforced plastic, a glass fiber reinforced plastic, or a carbon-glass hybrid fiber reinforced plastic.

In an embodiment, the window module may include a window protective layer. In the first cutting operation and the second cutting operation, the support plate, the panel protective layer, the display panel, and the window protective layer are cut to form cut side surfaces. The cut side surfaces each have a step less than or equal to about 100 μm or less.

In an embodiment, the preliminary foldable module may further include at least one adhesive layer. The at least one adhesive layer may be cut with the second laser beam in the second cutting operation.

According to an embodiment of the present disclosure, a method of manufacturing a display device includes preparing a preliminary foldable module including a first group including a support plate and a second group including a display panel, the first group is disposed on the second group. A first cutting operation that includes the cutting of the first group with a first laser beam is performed. Reflected light that is reflected from a surface of the second group exposed by cutting the first group is detected by a laser-sensing part. The first laser beam is changed to a second laser beam. A second cutting operation of cutting the second group with the second laser beam is performed. The support plate may include a carbon fiber reinforced plastic, a glass fiber reinforced plastic, or a the carbon-glass hybrid fiber reinforced plastic.

In an embodiment, the second group further may include a window module disposed under the display panel, and a panel protective layer disposed above the display panel.

In an embodiment, the support plate may not reflect the first laser beam, and the second group may reflect the first laser beam and the second laser beam.

In an embodiment, the first laser beam and the second laser beam may be output from a same laser apparatus. The first and second laser beams differ from each other only based on laser beam conditions. The preliminary foldable module may be substantially integrally cut.

In an embodiment, the first cutting operation and the second cutting operation may be performed in one cutting stage.

In an embodiment, an intensity of the first laser beam may be greater than an intensity of the second laser beam.

In an embodiment, the first laser beam and the second laser beam may be each emitted from the support plate toward the panel protective layer.

In an embodiment, the second group may further include at least one adhesive layer. The at least one adhesive layer may be cut with the second laser beam in the second cutting operation.

According to an embodiment of the present disclosure, a display device includes a support plate. A panel protective layer is disposed on the support plate. A display panel is disposed on the panel protective layer. A window module includes a window protective layer. The window module is disposed on the display panel. The support plate includes a carbon fiber reinforced plastic, a glass fiber reinforced plastic, or a carbon-glass hybrid fiber reinforced plastic. A side surface of each of the support plate, the panel protective layer, the display panel, and the window protective layer has a step less than or equal to about 100 μm.

In an embodiment, the display device may further include a digitizer disposed below the support plate.

### BRIEF DESCRIPTION OF THE DRAWINGS

The accompanying drawings are included to provide a further understanding of embodiments of the present disclosure, and are incorporated in and constitute a part of this specification. The drawings illustrate non-limiting embodiments of the present disclosure and, together with the description, serve to explain principles of the present disclosure. In the drawings:

FIG. 1A is a perspective view illustrating an unfolded state of a display device according to an embodiment of the present disclosure;

FIG. 1B is a perspective view illustrating an in-folded state of the display device according to an embodiment of the present disclosure;

FIG. 1C is a perspective view illustrating an out-folded state of the display device according to an embodiment of the present disclosure;

FIG. 2A is a perspective view illustrating an unfolded state of a display device according to an embodiment of the present disclosure;

FIG. 2B is a perspective view illustrating an in-folded state of the display device according to an embodiment of the present disclosure;

FIG. 3 is an exploded perspective view of a display device according to an embodiment of the present disclosure;

FIG. 4 is a cross-sectional view of a display device taken along line I-I′ of FIG. 3, according to an embodiment of the present disclosure;

FIG. 5 is a flowchart of a method of manufacturing a display device according to an embodiment of the present disclosure;

FIG. 6 is a schematic view of a laser apparatus according to an embodiment of the present disclosure; and

FIGS. 7A to 7E are cross-sectional views respectively illustrating operations of a method of manufacturing a display device according to an embodiment of the present disclosure.

### DETAILED DESCRIPTION OF EMBODIMENTS

The present disclosure may be implemented in various modifications and have various forms, and non-limiting embodiments are illustrated in the drawings and described in detail in the text. It is to be understood, however, that embodiments of the present disclosure are not intended to be limited to the particular forms disclosed, but on the contrary, is intended to cover all modifications, equivalents, and alternatives falling within the spirit and scope of the present disclosure.

In this specification, it will be understood that when an element (or region, layer, portion, or the like) is referred to as being “on”, “connected to” or “coupled to” another element, the element may be directly disposed/connected/coupled to another element, or intervening elements may be disposed therebetween.

In this specification, it will be understood that “being directly disposed” means that there are no intervening layers, films, regions, plates or the like between a portion of layers, films, regions, plates or the like and another portion. For example, “being directly disposed” may mean to be disposed between two layers or two members without using an additional member such as an adhesive member or like.

Like reference numerals or symbols refer to like elements throughout. In the drawings, the thickness, the ratio, and the dimension of the elements may be exaggerated for effective description of the technical contents.

The term “and/or” includes all combinations of one or more of the associated listed elements.

Although the terms first, second, etc., may be used to describe various elements, these elements should not necessarily be limited by these terms. These terms may only be used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, the terms such as “below”, “lower”, “above”, “upper” and the like, may be used herein for the description to describe the relationship of one element to another element illustrated in the figures. It will be understood that the terms have a relative concept and are described on the basis of the orientation depicted in the figures. In this specification, “being disposed on” may mean to be disposed not only on an upper part but also on a lower part of one member.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device and a method of manufacturing the display device according to an embodiment of the present disclosure will be described with reference to the accompanying drawings.

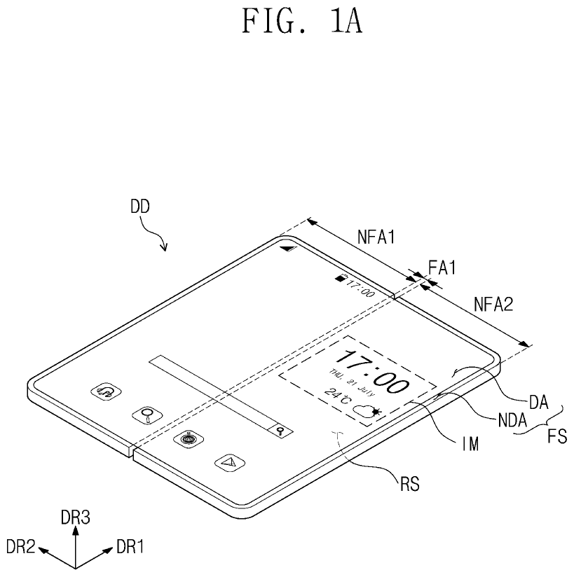

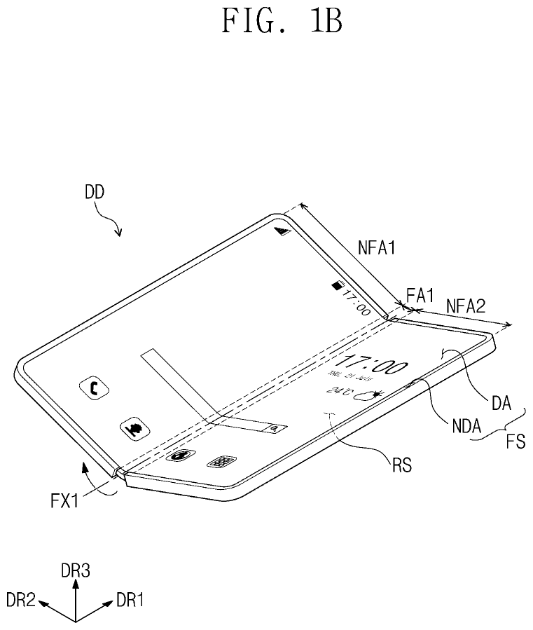

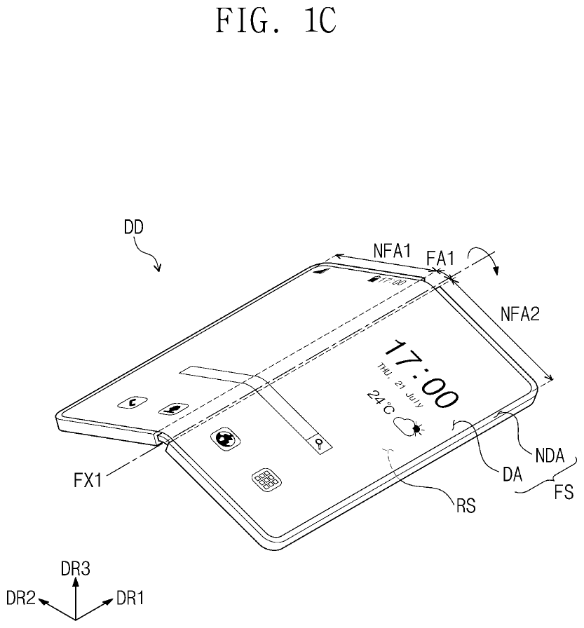

FIG. 1A is a perspective view illustrating an unfolded state of a display device DD according to an embodiment of the present disclosure. FIG. 1B is a perspective view illustrating an in-folded state of the display device DD according to an embodiment of the present disclosure. FIG. 1C is a perspective view illustrating an out-folded state of the display device DD according to an embodiment of the present disclosure.

The display device DD according to an embodiment may be a device activated in response to an electrical signal. For example, in an embodiment the display device DD may be a mobile phone, a tablet computer, a car navigation system, a game console, or a wearable device. However, embodiments of the present disclosure are not necessarily limited thereto. In FIG. 1A, etc., of the present specification, the display device DD is illustrated as a mobile phone for convenience of explanation.

In FIG. 1A and the following drawings, first, second and third directions DR1, DR2, and DR3 are illustrated, and the directions indicated by the first to third directions DR1, DR2, and DR3 illustrated herein have a relative concept and thus may be changed to other directions. Additionally, while the first to third directions DR1, DR2, DR3 are shown as being perpendicular to each other, embodiments of the present disclosure are not necessarily limited thereto and the first to third direction DR1, DR2, DR3 may cross each other at various different angles.

Referring to FIGS. 1A to 1C, the display device DD according to an embodiment may include a first display surface FS extending in a plane defined in the first direction DR1 and the second direction DR2 crossing the first direction DR1. The display device DD may provide an image IM to users through the first display surface FS. In the embodiment of FIG. 1A, the image IM is software application icons and a clock, temperature and calendar window. However embodiments of the present disclosure are not necessarily limited thereto and the image IM may be various different subject matter. The display device DD according to an embodiment may display, in the third direction DR3, the image IM on the first display surface FS parallel to each of the first direction DR1 and the second direction DR2. In this specification, a front surface (e.g., an upper surface) and a rear surface (e.g., a lower surface) of each component are defined based on a direction in which the image IM is displayed. The front surface and the rear surface may be arranged opposite to each other in the third direction DR3, and the normal direction of each of the front surface and the rear surface may be parallel to the third direction DR3.

The display device DD according to an embodiment may include the first display surface FS and a second display surface RS. The first display surface FS may include a display region DA and a non-display region NDA. In an embodiment, the display region DA may include an electronic module region. The second display surface RS may be defined as a surface opposite to at least a portion of the first display surface FS. For example, the second display surface RS may be defined as a portion of the rear surface of the display device DD.

The display device DD according to an embodiment may detect an external input applied from the outside. The external input may include various types of inputs applied from the outside of the display device DD. For example, in an embodiment the external input may include not only a touch by a part of the user's body such as user's hand but also an external input (e.g., hovering) applied while the user or an object approaches or is adjacent within a predetermined distance to the display device DD. In addition, in some embodiments the external input may have various forms such as force, pressure, temperature, light, and the like.

The display device DD may include a folding region FA1 and non-folding regions NFA1 and NFA2. The display device DD according to an embodiment may include a first non-folding region NFA1 and a second non-folding region NFA2 disposed with the folding region FA1 therebetween. For example, an embodiment of FIG. 1A shows the first non-folding region NFA1 and the second non-folding region NFA2 spaced apart from each other in the second direction DR2 with the folding region FA1 disposed therebetween. Embodiments of FIGS. 1A to 1C illustrate the display device DD including one folding region FA1. However, embodiments of the present disclosure are not necessarily limited thereto. For example, in an embodiment a plurality of folding regions may be defined in the display device DD and may be variously arranged with respect to a plurality of non-folding regions.

Referring to FIG. 1B, the display device DD according to an embodiment may be folded with respect to a first folding axis FX1. The first folding axis FX1 may be an imaginary axis (e.g., a virtual axis) extending in the first direction DR1 and is parallel to a relatively long-side direction of the display device DD. On the first display surface FS, the first folding axis FX1 may extend along the first direction DR1.

In an embodiment, the first and second non-folding regions NFA1 and NFA2 may be disposed directly adjacent to the folding region FA1 while sandwiching (e.g., surrounding) the folding region FA1. For example, the first non-folding region NFA1 may be disposed on a first side of the folding region FA1 along the second direction DR2, and the second non-folding region NFA2 may be disposed on an opposite second side of the folding region FA1 along the second direction DR2.

The display device DD may be folded with respect to the first folding axis FX1 and be changed into an in-folded state where in the first display surface FS, a first region overlapping the first non-folding region NFA1 and a second region overlapping the second non-folding region NFA2 face each other. In an embodiment, the second display surface RS of the display device DD may be visible to users in an in-folded state. The second display surface RS may further include an electronic module region in which an electronic module including various components is disposed. However, embodiments of the present disclosure are not necessarily limited thereto.

Referring to FIG. 1C, the display device DD according to an embodiment may be folded with respect to the first folding axis FX1 and be changed into an out-folded state where in the second display surface RS, a first region overlapping the first non-folding region NFA1 and a second region overlapping the second non-folding region NFA2 face each other. However, embodiments of the present disclosure are not necessarily limited thereto, and the display device DD may be folded with respect to a plurality of folding axes such that respective portions of the first display surface FS and the second display surface RS face each other. The number of folding axes and the number of non-folding regions corresponding thereto are not necessarily limited to those shown in FIGS. 1A-1C.

In an embodiment, the display device DD may further include various electronic modules. For example, the electronic module may include at least one of a camera, a speaker, a light detection sensor, or a heat detection sensor. The electronic module may detect an external subject received through the first display surface FS or the second display surface RS or provide a sound signal such as voice to the outside through the first display surface FS or the second display surface RS. The electronic module may include a plurality of components, and is not necessarily limited to any one embodiment.

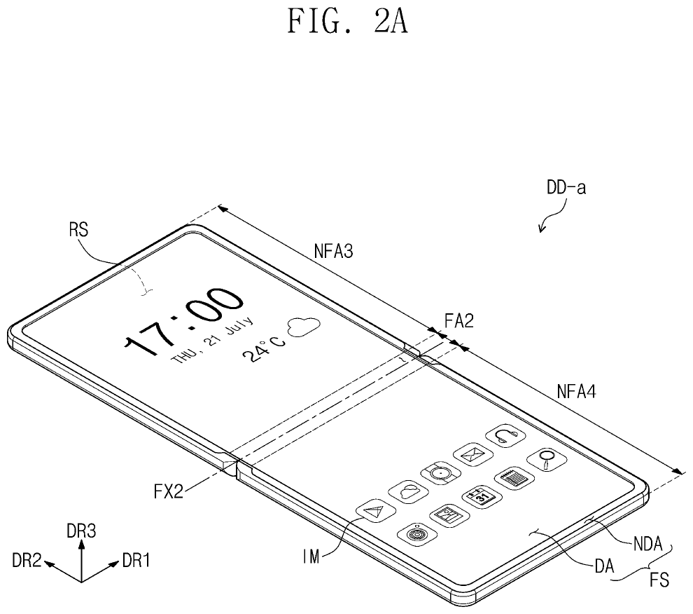

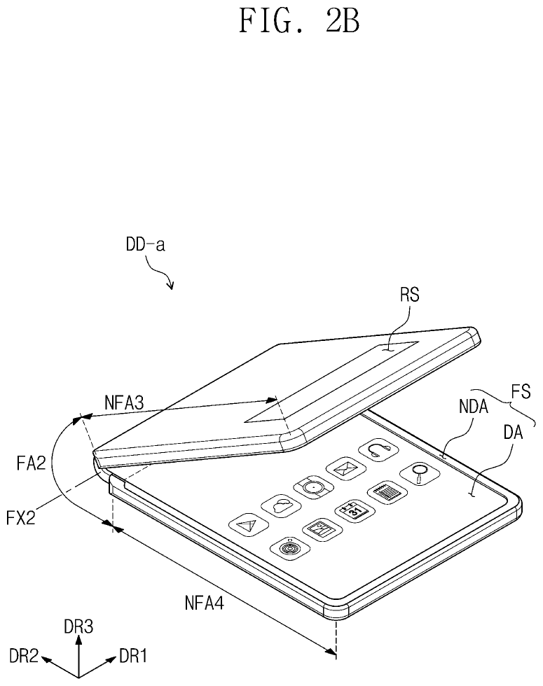

FIG. 2A is a perspective view illustrating an unfolded state of a display device DD according to an embodiment of the present disclosure. FIG. 2B is a perspective view illustrating an in-folded state of the display device DD according to an embodiment of the present disclosure.

A display device DD-a according to an embodiment may be folded with respect to a second folding axis FX2 extending in a direction parallel to the first direction DR1. An embodiment of FIG. 2B illustrates that an extending direction of the second folding axis FX2 is parallel to an extending direction of a relatively short side of the display device DD-a. However, embodiments of the present disclosure are not necessarily limited thereto.

The display device DD-a according to an embodiment may include at least one folding region FA2 and third and fourth non-folding regions NFA3 and NFA4 adjacent to the folding region FA2 (e.g., in the second direction DR2). The third and fourth non-folding regions NFA3 and NFA4 may be disposed to be spaced apart from each other (e.g., in the second direction DR2) with the folding region FA2 therebetween.

In an embodiment, the third non-folding region NFA3 and the fourth non-folding region NFA4 may face each other, and the display device DD-a may be in-folded such that a display surface FS is not exposed to the outside. Additionally, in an embodiment, the display device DD-a may be out-folded such that the display surface FS is exposed to the outside. In addition, the display device DD-a according to an embodiment may include a first display surface FS and a second display surface RS, and the first display surface FS may include a display region DA and a non-display region NDA. Furthermore, the display device DD-a may further include various electronic modules.

The display devices DD and DD-a, according to the foregoing embodiments described with reference to FIGS. 1A to 1C and FIGS. 2A and 2B may be configured to repeatedly perform an in-folding or out-folding operation from an unfolding operation and vice versa. However, embodiments of the present disclosure are not necessarily limited thereto. In an embodiment, the display devices DD and DD-a may be configured to select at least one of an unfolding operation, in-folding operation, or out-folding operation. Also, the display device according to an embodiment may include a plurality of folding regions or may be a flexible display device in which at least some regions are bendable or rollable.

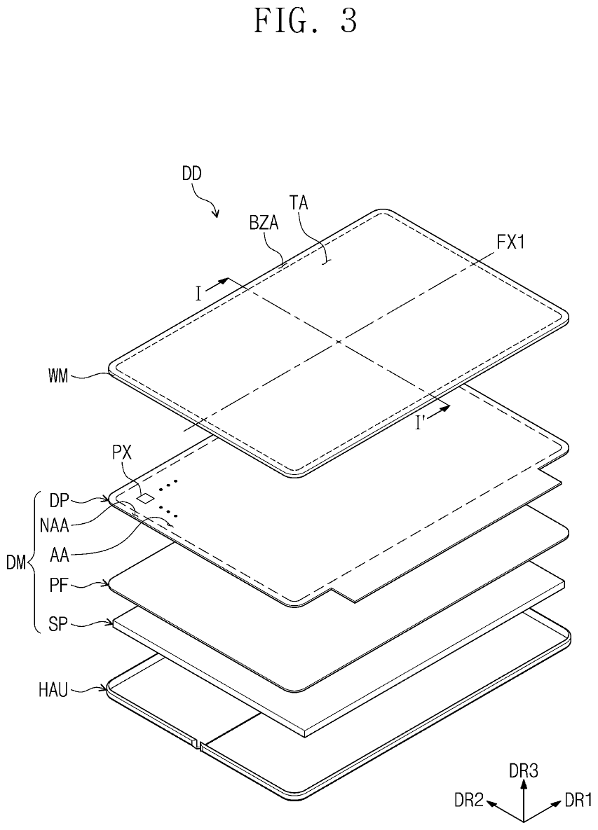

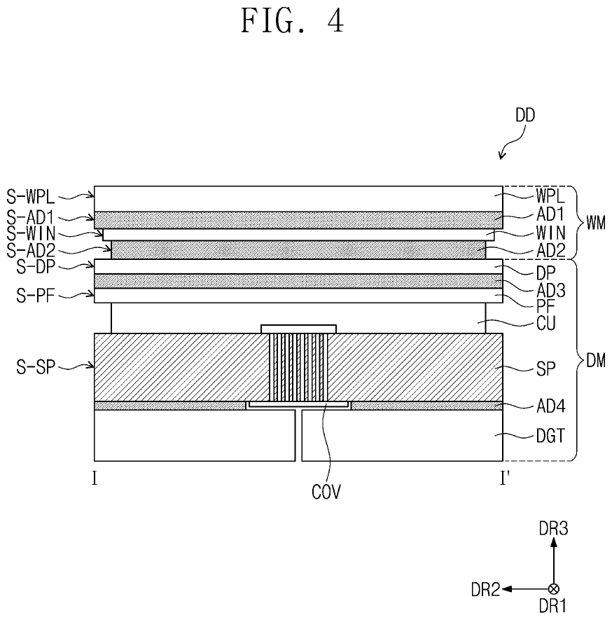

FIG. 3 is an exploded perspective view of a display device DD according to an embodiment of the present disclosure. FIG. 4 is a cross-sectional view of a display device DD according to an embodiment of the present disclosure. FIG. 3 illustrates an exploded perspective view of the display device DD, according to an embodiment, illustrated in FIG. 1A. FIG. 4 illustrates a cross-sectional view taken along line I-I′ of the display device DD, according to an embodiment, illustrated in FIG. 3.

Referring to FIGS. 3 and 4, the display device DD according to an embodiment includes a display module DM and a window module WM. The window module WM may be disposed on at least a portion of an upper part (e.g., an upper surface) or a lower part (e.g., a lower surface) of the display module DM. FIGS. 3 and 4 illustrate that the window module WM is disposed on an upper part (e.g., an upper surface) of the display module DM for convenience of explanation.

The display module DM according to an embodiment includes a support plate SP, a panel protective layer PF disposed on the support plate, and a display panel DP disposed on the panel protective layer PF.

The support plate SP according to an embodiment may be a layer which is disposed on a lower part (e.g., a lower surface) of the display panel DP and supports the display panel DP. In an embodiment, the support plate SP may be made of a non-metal material. Since the support plate SP is made of a non-metal material rather than a metal material, a signal transmitted to a digitizer DGT (FIG. 4) may not be blocked by interference due to metal in the support plate SP. In addition, the support plate SP may be lighter than a metal plate made of a metal material, thereby achieving lightness of the display device DD.

In an embodiment, the support plate SP may be made of a reinforced fiber composite material. For example, the support plate SP may be a carbon fiber reinforced plastic (CFRP). In an embodiment in which the support plate SP is a carbon fiber reinforced plastic, the support plate SP may have excellent strength and an excellent folding characteristic. In addition, the support plate SP may be easily processed through a laser process or a microblast process. Furthermore, in an embodiment the support plate SP may be a glass fiber reinforced plastic (GFRP), or a carbon-glass hybrid fiber reinforced plastic (HFRP).

A folding part of the support plate SP corresponding to the folding region FA1 (see FIGS. 1A to 1C) may have predetermined patterns such that the folding part becomes deformable. For example, FIG. 4 illustrates that the folding part of the support plate SP has a lattice shape in which a plurality of openings are defined. The plurality of openings may be formed through a laser process or a microblast process. Since the folding part of the support plate SP has a lattice shape, the flexibility of the folding region FA1 (see FIGS. 1A to 1C) may be increased. For example, the support plate SP may be easily folded on the basis of the folding region FA1 (see FIGS. 1A to 1C).

In an embodiment, a cover layer COV may be disposed on a lower surface of the support plate SP. The cover layer COV may cover a lattice-like portion defined in the support plate SP from below the support plate SP. In an embodiment, the cover layer COV may overlap the folding region FA1 (see FIGS. 1A to 1C), and may not overlap the first and second non-folding regions NFA1 and NFA2 (see FIGS. 1A to 1C). For example, the cover layer COV may not be disposed in the first and second non-folding regions NFA1 and NFA2 (see FIGS. 1A to 1C). In an embodiment, the cover layer COV may have a lower elastic modulus than the support plate SP. For example, in an embodiment the cover layer COV may include thermoplastic polyurethane or rubber. However, embodiments of the present disclosure are not necessarily limited thereto and a material of the cover layer COV may vary. In an embodiment, the cover layer COV may be manufactured in a sheet form and be attached to the lower surface of the support plate SP.

The digitizer DGT according to an embodiment may be disposed on a lower part (e.g., a lower surface) of the support plate SP. The cover layer COV may be disposed between the support plate SP and the digitizer DGT (e.g., in the third direction DR3). The cover layer COV may be disposed to be spaced apart from an upper surface of the digitizer DGT (e.g., in the third direction DR3).

In an embodiment, the digitizer DGT may receive information about a position which is indicated by a user on the display surface FS (see FIG. 1A). The digitizer DGT may be configured in an electromagnetic manner (e.g., an electromagnetic resonance manner). For example, in an embodiment the digitizer DGT may include a digitizer sensor substrate including a plurality of coils. However, the digitizer DGT is not necessarily limited thereto, and the digitizer DGT may be configured in an active electrostatic manner, etc.

When a user moves a pen on the display device DD, the pen is driven by an alternating current signal so as to cause a vibrating magnetic field, and thus the vibrating magnetic field may induce a signal to coils. A position of the pen may be detected by the signal induced to the coils. The digitizer DGT may detect an electromagnetic change caused by the pen approaching, thereby determining the position of the pen.

In a comparative embodiment in which the support plate SP, which is disposed on the digitizer DGT and is arranged adjacent to the digitizer DGT, includes a metal, the digitizer DGT may have a low sensitivity due to the metal. For example, when a signal transmitted on the display device DD is blocked due to a signal interference caused by a metal plate, the digitizer DGT may not function normally. In an embodiment of the present disclosure, since the support plate SP disposed on the digitizer DGT is composed of a reinforced fiber composite which is a non-metal material, the digitizer DGT may function normally.

The digitizer DGT may be divided into two portions in a folding region FA. In an embodiment, the mutually separated portions of the digitizer DGT may each be connected to a digitizer driver through flexible circuit boards.

The width of the digitizer DGT may be substantially the same as the width of the support plate SP, or may be less than the width of the support plate SP.

Also, the display module DM according to an embodiment may further include a shielding layer and/or a heat dissipation layer which are disposed under the digitizer DGT. The shielding layer may shield electromagnetic waves which may be applied to the digitizer DGT from below the display device DD. The heat dissipation layer may perform a heat dissipation function. In an embodiment, the heat dissipation layer may include graphite. However, embodiments of the present disclosure are not necessarily limited thereto.

The panel protective layer PF according to an embodiment may be a layer which is disposed under the display panel DP and protects a rear surface of the display panel DP. In an embodiment, the panel protective layer PF may overlap an entirety of the display panel DP. The panel protective layer PF may include a polymer material. For example, in an embodiment the panel protective layer PF may be a polyimide (PI) film or a polyethylene terephthalate (PET) film.

The display panel DP according to an embodiment may display the image IM (see FIG. 1A) in response to an electrical signal and transmit/receive information about an external input. The display panel DP may include a display layer and a sensor layer disposed on the display layer.

The display panel DP may include an active region AA and a peripheral region NAA. The active region AA may be a region in which the image IM (see FIG. 1A) is provided. Pixels PX may be arranged in the active region AA. The peripheral region NAA may be adjacent to the active region AA (e.g., in the first and second directions DR1, DR2). For example, in an embodiment the peripheral region NAA may surround the active region AA (e.g., in the first and second directions DR1, DR2). However, embodiments of the present disclosure are not necessarily limited thereto. A driving circuit, a driving line, etc., for driving the active region AA may be disposed in the peripheral region NAA. The active region AA and the peripheral region NAA may respectively correspond to the display region DA and the non-display region NDA which are illustrated in FIG. 1A.

The display panel DP may include a plurality of pixels PX. The pixels PX may each display light in response to an electrical signal. The light displayed by the pixels PX may form the image IM (see FIG. 1A). The pixels PX may each include a display element. For example, in an embodiment the display element may be an organic light-emitting element, an inorganic light-emitting element, an organic-inorganic light-emitting element, a micro LED, or a nano LED, a quantum dot light-emitting element, an electrophoretic element, an electrowetting element, and the like. However, embodiments of the present disclosure are not necessarily limited thereto.

The display module DM according to an embodiment may further include an impact absorbing layer. The impact absorbing layer according to an embodiment may disposed on the display panel DP. The impact absorbing layer may absorb an external impact applied from above the display device DD toward the display panel DP, thereby protecting the display panel DP. The impact absorbing layer may be in the form of a stretched film. The impact absorbing layer may include a polymer material. For example, in an embodiment the impact absorbing layer may be a polyimide (PI) film or a polyethylene terephthalate (PET) film. However, embodiments of the present disclosure are not necessarily limited thereto.

A cushion layer CU according to an embodiment may be a functional layer which is used to protect the display panel DP against external impacts, etc., transmitted from therebelow. For example, in an embodiment the cushion layer CU may include an elastomer, etc., such as a sponge, a foam, or a urethane resin. However, embodiments of the present disclosure are not necessarily limited thereto. In an embodiment, a barrier film, which is made of polyimide (PI) or polyethylene terephthalate (PET), may be applied together with the cushion layer CU to increase the function of the cushion layer CU. In an embodiment, the width of the cushion layer CU may be less than the width of the panel protective layer PF.

Also, the display module DM according to an embodiment may further include at least one adhesive layer to bond the layers together. In an embodiment, the at least one adhesive layer may be an optically clear adhesive film (OCA) or an optically clear adhesive resin layer (OCR). For example, as illustrated in FIG. 4, the adhesive layers AD3 and AD4 may respectively be disposed between the display panel DP and the panel protective layer PF (e.g., in the third direction DR3), and between the support plate SP and the digitizer DGT (e.g., in the third direction DR3).

In an embodiment, the window module WM may cover an entirety of the upper surface of display module DM. The window module WM may have a shape corresponding to the shape of the display module DM. The window module WM may have flexibility such that the window module WM is deformable as the display device DD is folded or bent. The window module WM may function to protect the display module DM against an external impact.

In an embodiment, the window module WM may include a transmission region TA and a bezel region BZA. The transmission region TA may overlap at least a portion of the active region AA of the display module DM. The transmission region TA may be an optically transparent region. For example, in an embodiment the transmission region TA may have a transmittance of about 90% or more with respect to light having a visible light wavelength range. The image IM (see FIG. 1A) may be provided to a user through the transmission region TA, and the user may obtain information through the image IM (see FIG. 1A).

The bezel region BZA may be a region having a relatively lower light transmittance than the transmission region TA. The bezel region BZA may define a shape of the transmission region TA. In an embodiment, the bezel region BZA may have a predetermined color. The bezel region BZA may cover the peripheral region NAA of the display module DM, and thus may block the peripheral region NAA from being viewed from the outside by a user. However, embodiments of the present disclosure are not necessarily limited thereto. For example, the bezel region BZA may be omitted in the window module WM in some embodiments.

Referring to FIG. 4, the window module WM may include a window WIN and a window protective layer WPL disposed on the window WIN.

The window WIN according to an embodiment may include a chemically strengthened glass substrate GL. The window WIN according to an embodiment may include ultra-thin glass (UTG). Since the window WIN includes ultra-thin glass, the occurrence of wrinkles may be reduced even when the folding and unfolding is repeated. For example, in an embodiment the window WIN may have a thickness in a range of about 20 μm to about 100 μm. The window WIN may have a thickness within the above range and the window WIN may also have an appropriate hardness as well to provide bendability or foldability so that the window WIN may be used for a flexible display device.

In an embodiment, the window WIN may include a synthetic resin film instead of a glass substrate. For example, in an embodiment the window WIN may include polyimide, polycarbonate, polyamide, triacetylcellulose, or polymethylmethacrylate, or polyethylene terephthalate. However, embodiments of the present disclosure are not necessarily limited thereto.

The width of the window WIN according to an embodiment may be less than the width of the window protective layer WPL. In this specification, the width may mean a length thereof in the second direction DR2. Accordingly, a side surface S-WIN of the window WIN may be positioned more inward than a side surface S-WPL of the window protective layer WPL.

In an embodiment, a printed layer may further be included in at least a portion of an upper surface or a lower surface of the window WIN. For example, in an embodiment the printed layer may be formed on a lower surface of the window WIN through a printing or deposition process and be directly disposed on a lower surface of the window WIN. The printed layer may be disposed on at least a portion of the lower surface of the window WIN and may define the bezel region BZA. For example, the printed layer may be a portion corresponding to the peripheral region NAA of the display module DM. The printed layer may have a relatively lower light transmittance than the window WIN. For example, the printed layer may have a predetermined color. Accordingly, the printed layer may selectively transmit or reflect only light having a predetermined color. The printed layer may be a light blocking layer that absorbs incident light.

The window protective layer WPL according to an embodiment may be disposed above the window WIN (e.g., in the third direction DR3) and may be the uppermost layer of the display device DD. The window protective layer WPL may be a layer exposed on the outermost surface of the display device DD and may function to protect the window WIN, the display module DM, and the like. The window protective layer WPL may have a single-or multi-layered structure.

The window module WM according to an embodiment may further include at least one adhesive layer. For example, as illustrated in FIG. 4, the window module WM may include a first adhesive layer AD1 disposed between the window WIN and the window protective layer WPL (e.g., in the third direction DR3). In addition, the window module WM may include a second adhesive layer AD2 disposed between the window WIN and the display module DM (e.g., in the third direction DR3). The first and second adhesive layers AD1 and AD2 may respectively bond the window WIN and the window protective layer WPL to each other, and the window module WM and the display module DM to each other. In an embodiment, the first and second adhesive layers AD1 and AD2 may be optically clear adhesive films (OCA) or optically clear adhesive resin layers (OCR). However, embodiments of the present disclosure are not necessarily limited thereto.

The width of the first adhesive layer AD1 according to an embodiment may be substantially the same as the width of the window protective layer WPL. For example, a side surface S-AD1 of the first adhesive layer AD1 may substantially correspond to or be aligned with the side surface S-WPL of the window protective layer WPL (e.g., in the second direction DR2).

Also, the width of the second adhesive layer AD2 may be less than the width of the first adhesive layer AD1. For example, a side surface S-AD2 of the second adhesive layer AD2 may be positioned more inward than the side surface S-AD1 of the first adhesive layer AD1. Accordingly, when the display device DD is folded, the first adhesive layer AD1 may not be in direct contact with the second adhesive layer AD2.

The second adhesive layer AD2 may bond the window module WM and the display module DM to each other and may also serve as the above-described impact absorbing layer. In an embodiment, the second adhesive layer AD2 may have a thickness in a range of about 10 μm to about 150 μm. For example, the second adhesive layer AD2 may have a thickness in a range of about 20 μm to about 120 μm. In an embodiment in which the second adhesive layer AD2 has a thickness within the above range, the second adhesive layer AD2 may sufficiently protect the display panel DP against an external impact.

The window module WM according to an embodiment may further include a window functional layer including at least one of a hard coating layer or an anti-fingerprint layer. The window functional layer may be a layer which functions as a hard coating layer or an anti-fingerprint layer, or functions as both a hard coating layer and an anti-fingerprint layer. The hard coating layer may be a layer which imparts physical strength to the window module WM. The anti-fingerprint layer may be a layer which prevents external contamination such as fingerprints, etc., and suppresses wear caused by external friction. In an embodiment, the window functional layer may further include an anti-reflective or anti-glare function.

The display device DD according to an embodiment may further include an electronic module disposed below the display module DM. For example, in an embodiment the electronic module may include a wireless communication module, a camera module, a proximity sensor module, a video input module, an audio input module, an audio output module, a memory, an external interface module, and the like. However, embodiments of the present disclosure are not necessarily limited thereto.

The electronic module may include a main driver (e.g., a main controller). The main driver may control the overall operation of the display device DD. For example, the main driver may activate or deactivate the display device DD according to user inputs. The main driver may contain at least one microprocessor.

Also, the display device DD according to an embodiment may further include a polarizing film disposed between the display module DM and the second adhesive layer AD2 (e.g., in the third direction DR3). The polarizing film may be a film having an optical function for increasing the light extraction efficiency of the display module DM. The polarizing film may include a retarder and/or a polarizer.

The display device DD according to an embodiment may further include a housing HAU that accommodates the display module DM, a lower functional layer, and the like. The housing HAU and the window module WM may be coupled to form the exterior of the display device DD. In an embodiment, the housing HAU may include a material having relatively high rigidity. For example, the housing HAU may include a plurality of frames and/or plates composed of glass, plastic, or metal. However, embodiments of the present disclosure are not necessarily limited thereto. The display module DM may be accommodated inside the accommodation space of the housing HAU for protection against an external impact. In an embodiment, the housing HAU may further include a hinge structure for facilitating a folding or bending operation.

In the display device DD according to an embodiment of the present disclosure, side surfaces of a plurality of layers included in the display device DD may substantially correspond to or be aligned with each other when viewed from the top. For example, in an embodiment, a step between the side surfaces of the plurality of layers included in the display device DD may be less than or equal to about 100 μm. When the step between the side surfaces of the plurality of layers is less that or equal to about 100 μm or less, the absolute value of position differences between the side surfaces of the layers may be about 100 μm or less when viewed from the top.

For example, referring to FIG. 4, steps between a side surface S-SP of the support plate SP, a side surface S-PF of the panel protective layer PF, a side surface S-DP of the display panel DP, and a side surface S-WPL of the window protective layer WPL may each be less than or equal to about 100 μm. For example, in an embodiment the steps may each be less than or equal to about 50 μm.

Additionally, in an embodiment steps between side surfaces of the first to fourth adhesive layers AD1 to AD4 with the above-mentioned layers may each also be less than or equal to about 100 μm. For example, respective steps between the side surface S-AD1 of the adhesive layer AD1 included in the window module WM and the side surface S-SP of the support plate SP, the side surface S-PF of the panel protective layer PF, the side surface S-DP of the display panel DP, and the side surface S-WPL of the window protective layer WPL, which have been described above, may be less than or equal to about 100 μm. For example, in an embodiment the steps may each be less than or equal to about 50 μm.

According to a later-described method of manufacturing a display device DD of the present disclosure, respective layers included in the display device DD are stacked and then integrally cut, thereby reducing the steps between the side surfaces of the layers of the display device DD. For example, in a comparative embodiment in which the layers are bonded to other layers without being integrally cut, but with being additionally cut after each layer or some layers are separately stacked, there may be relatively large steps between the side surfaces of the layers of the display device DD due to tolerances caused by stacking the layers. For example, as one stacking operation is added, the stacking operation may cause a step of about 125 μm between the layers.

As described above, the side surfaces of the plurality of layers included in the display device DD according to an embodiment of the present disclosure may substantially correspond to each other when viewed from the top, and steps between the side surfaces may be less than or equal to about 100 μm, such as less than or equal to about 50 μm. Therefore, the display device DD according to the present disclosure may have a reduced dead space caused by the step between the side surfaces and have a reduced peripheral region NAA of the display device DD.

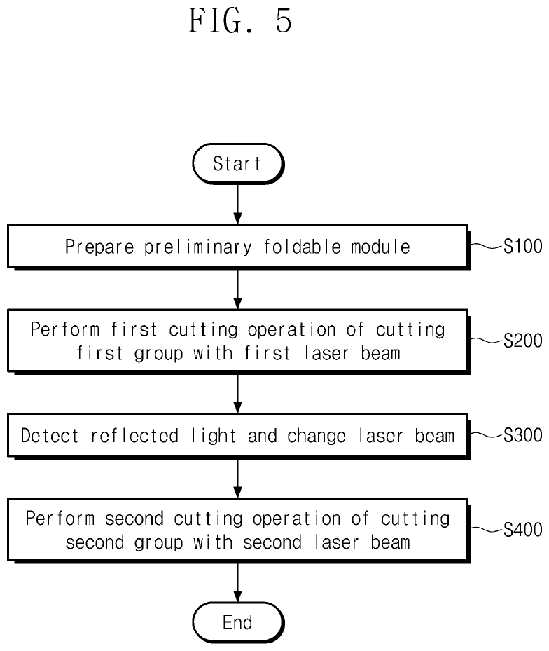

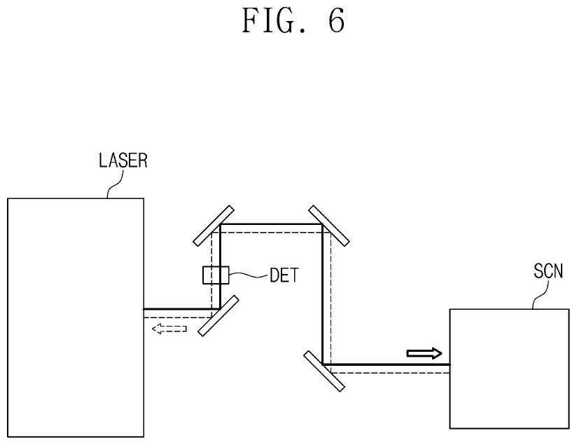

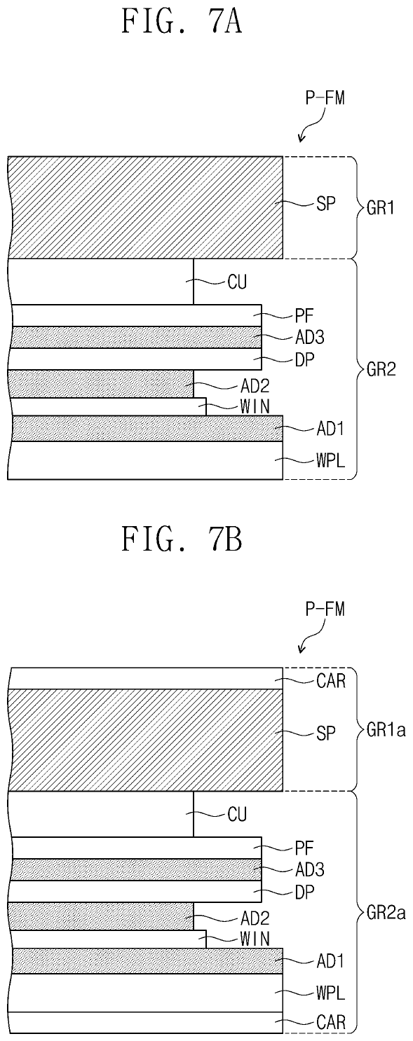

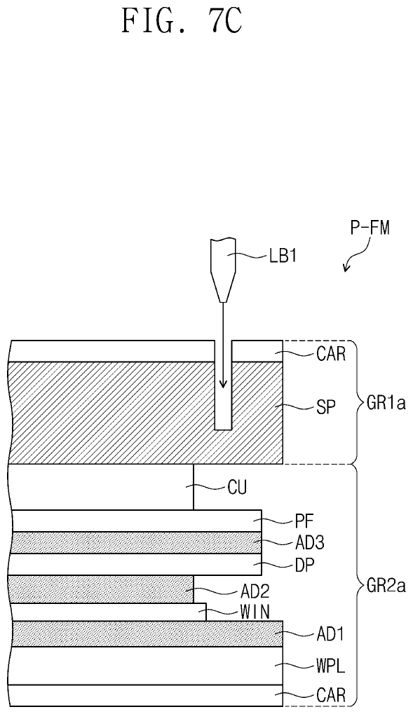

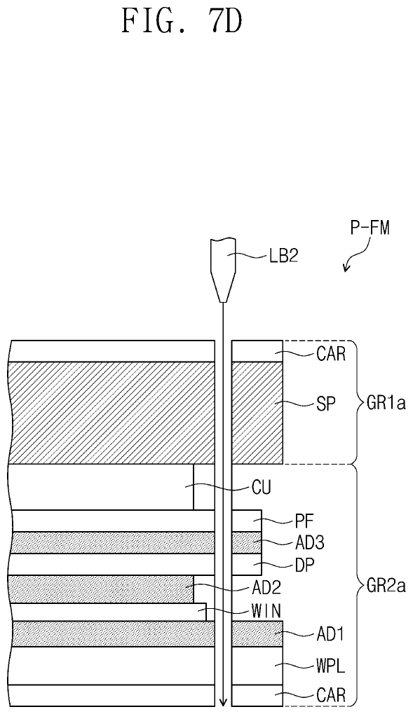

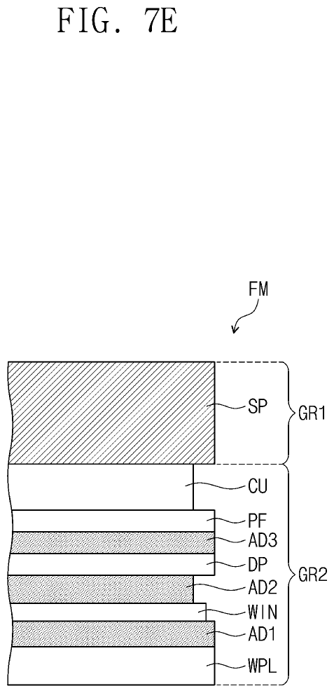

FIG. 5 is a flowchart of a method of manufacturing a display device according to an embodiment of the present disclosure. FIG. 6 is a schematic view of a laser apparatus according to an embodiment of the present disclosure. FIGS. 7A to 7E are cross-sectional views respectively illustrating operations of a method of manufacturing a display device according to embodiments of the present disclosure.

FIG. 5 may illustrate a method of manufacturing the display devices DD and DD-a, according to embodiments described with reference to FIGS. 1A to 4.

Referring to FIG. 5, the method of manufacturing the display device according to an embodiment may include preparing a preliminary foldable module P-FM (see FIG. 7A) in block S100, performing a first cutting operation of cutting a first group GR1a (see FIG. 7C) with a first laser beam LB1 (see FIG. 7C) in block S200, detecting the reflected light and changing a laser beam in block S300, and performing a second cutting operation of cutting a second group GR2a (see FIG. 7D) with a second laser beam LB2 (see FIG. 7D) in block S400.

Referring to FIG. 6, the laser apparatus according to an embodiment may include a laser output unit LASER, a scan unit SCN, and a laser-sensing part DET. In an embodiment, the laser output unit LASER may output a laser beam according to input laser conditions. The scan unit SCN may allow the laser beam to be emitted to an object. The laser-sensing part DET (e.g., a sensing portion) may detect reflected light that is the reflected laser beam having arrived thereat from the scan unit SCN. According to an embodiment of the present disclosure, when the laser-sensing part DET detects the reflected light that is the reflected laser beam having arrived thereat form the scan unit SCN, the laser output unit LASER may change the first laser beam LB1 (see FIG. 7C) to the second laser beam LB2 (see FIG. 7D).

FIGS. 7A to 7E are cross-sectional views respectively enlarging one side surface to illustrate the method of manufacturing the display device according to embodiments of the present disclosure.

FIG. 7A is a cross-sectional view illustrating an operation of preparing the preliminary foldable module P-FM in block S100 (see FIG. 5). The preliminary foldable module P-FM may have a stacked structure in a state in which the side surfaces of the plurality of layers included in the display device DD are not cut yet (see FIG. 1A).

Referring to FIG. 7A, in the operation of preparing the preliminary foldable module P-FM in block S100 (see FIG. 5), the preliminary foldable module P-FM may include a second group GR2 and a first group GR1 disposed on (e.g., disposed directly thereon) the second group GR2.

The first group GR1 may include a layer which may be cut by a later-described first laser beam LB1 (see FIG. 7C). For example, the first group GR1 may include a support plate SP. In an embodiment, the support plate SP may include a non-metal material, such as the carbon fiber reinforced plastic, a glass fiber reinforced plastic, or a carbon-glass hybrid fiber reinforced plastic. However, embodiments of the present disclosure are not necessarily limited thereto and the first group GR1 may further include another layer which may be cut by the first laser beam LB1 (see FIG. 7C) and have a side surface positioned more inward than a cutting position.

The second group GR2 may include a layer which may be cut by a later-described second laser beam LB2 (see FIG. 7D). For example, in an embodiment the second group GR2 may include a window protective layer WPL, a display panel DP, a panel protective layer PF, and first to third adhesive layers AD1 to AD3. In an embodiment, the second group GR2 may further include a layer which has a side surface positioned more inward than a cutting position. For example, in an embodiment the second group GR2 may further include a window WIN, a second adhesive layer AD2, and a cushion layer CU. For example, the second group GR2 may include the window module WM (FIG. 4). However, embodiments of the present disclosure are not necessarily limited thereto and the second group GR2 may further include another layer which may be cut (e.g., sequentially cut) by the second laser beam LB2 (see FIG. 7D) and have a side surface positioned more inward than a cutting position.

FIG. 7B is a cross-sectional view illustrating an operation of loading the preliminary foldable module P-FM into a cutting stage. In an embodiment, the cutting stage may be a laser cutting stage.

Referring to FIG. 7B, carrier films CAR may be respectively attached to (e.g., attached directly thereto) an upper surface and a lower surface of the preliminary foldable module P-FM. The carrier films CAR may prevent the preliminary foldable module P-FM from being contaminated or damaged in an operation of loading/unloading the preliminary foldable module P-FM into the cutting stage or in an operation of cutting the preliminary foldable module P-FM. The first group GR1a and the second group GR2a, which are illustrated in FIG. 7B, may be defined as the same as the first group GR1 and the second group GR2 of FIG. 7A, respectively, except that the first group GR1a and the second group GR2a include the carrier films CAR.

FIG. 7C is a cross-sectional view illustrating the first cutting operation of cutting the first group GR1a with the first laser beam LB1 in block S200 (see FIG. 5). The first laser beam LB1 may be emitted from the support plate SP towards the panel protective layer PF.

Referring to FIG. 7C, the support plate SP may be cut by the first laser beam LB1. In an embodiment, the intensity of the first laser beam LB1 may be greater than the intensity of the later-described second laser beam LB2 (see FIG. 7D). Therefore, the side surface of the support plate SP, which requires higher energy than the second group GR2 (see FIG. 7A) during the laser cutting, may be uniformly cut and a periphery of a cut portion may not be damaged. For example, the condition (e.g., output power) for the first laser beam LB1 may be in a range of about 20 W to about 50 W.

In an embodiment, the support plate SP may not reflect light emitted by the laser. Accordingly, in the first cutting operation of cutting the first group GR1a with the first laser beam LB1 in block S200 (see FIG. 5), the reflected light may not be detected by the laser-sensing part DET (see FIG. 6).

FIG. 7D is a cross-sectional view illustrating an operation of detecting the reflected light and changing the laser beam in block S300 (see FIG. 5) and the second cutting operation of cutting the second group GR2a with the second laser beam LB2 in block S400 (see FIG. 5). Similar to the first laser beam LB1, the second laser beam LB2 may also be emitted from the support plate SP towards the panel protective layer PF.

In an embodiment, the operation of changing the laser beam in block S300 (see FIG. 5) may include detecting, with the laser-sensing part DET (see FIG. 6), the reflected light from the surface of the panel protective layer PF exposed by cutting the support plate SP, and changing the first laser beam LB1 to the second laser beam LB2.

The panel protective layer PF may reflect laser. Accordingly, the laser apparatus is set to automatically change a laser beam condition from the first laser beam LB1 to the second laser beam LB2 having lower energy than the first laser beam LB1 when the light reflected from the panel protective layer PF is detected, and thus the second group GR2a may be cut without damaging the periphery of the cut portion of the second group GR2a. For example, in an embodiment the second laser beam LB2 may have an output power in a range of about 1 W to about 20 W. The light reflected from the panel protective layer PF is detected by a laser-sensing part DET during the second cutting operation performed in block S400.

In an embodiment, the panel protective layer PF, the display panel DP, the window protective layer WPL, and the first to third adhesive layers AD1 to AD3 may reflect the emitted laser. Accordingly, in the second cutting operation of cutting the second group GR2a (e.g., sequentially cutting the elements of the second group GR2a) with the second laser beam LB2 in block S400 (see FIG. 5), the reflected light may be detected by the laser-sensing part DET (see FIG. 6).

FIG. 7E is a cross-sectional view illustrating a state in which a cut foldable module FM is unloaded from the cutting stage, and the carrier films CAR (see FIG. 7D) are removed.

The first and second cutting operations in blocks S200 and S400 (see FIG. 5) may integrally be performed in the same single cutting stage (e.g., one cutting stage). For example, the first laser beam LB1 and the second laser beam LB2 may be output from the same laser apparatus, and differs from each other only in terms of laser beam conditions (e.g., output power), and the preliminary foldable module P-FM (see FIGS. 7A to 7D) may be substantially integrally cut. For example, being “substantially integrally cut” may include being cut in a same cutting process in which first and second cutting operations only differs from each other based on laser conditions of first and second laser beams LB1, LB2.

For example, the changing of the laser beam condition may include changing the energy of the laser beam (e.g., output power), but is not necessarily limited to a specific range of energy. In addition, the substantially integrally cutting of the preliminary foldable module P-FM may indicate that the foldable module FM is cut through a single processing operation and thus a step between cut side surfaces of the foldable module FM become extremely small.

Accordingly, since there is no step between the side surfaces of the foldable module FM caused by stacking the layers, the cut side surfaces of the support plate SP, the panel protective layer PF, the display panel DP, and the window protective layer WPL may substantially correspond to or be aligned with each other when viewed from the top. For example, in an embodiment steps between the cut side surfaces of the layers of the foldable module FM may each be less than or equal to about 100 μm, for example, less than or equal to about 50 μm. Therefore, it is possible to reduce a dead space of the display device DD (see FIG. 1A).

Since the first and second cutting operations in blocks S200 and S400 (see FIG. 5) are integrally performed, it is possible to reduce the number of times of attachment/detachment of the carrier films CAR accompanying the cutting operation. Therefore, it is possible to reduce a rate of peeling defects which may occur when the carrier films CAR are peeled off.

The contents described above described with reference to FIGS. 3 and 4 may be similarly applied to the support plate SP, the cushion layer CU, the panel protective layer PF, the display panel DP, the window WIN, the window protective layer WPL, and the first, second, and third adhesive layers AD1, AD2, and AD3, which have been described in FIG. 5 and FIGS. 7A to 7E.

According to the description above, a step between side surfaces of layers included in a display device according to embodiments of the present disclosure may be reduced, and thus the display device may have a reduced dead space.

Also, in a method of manufacturing a display device according to an embodiment of the present disclosure, since layers included in a display device are integrally cut, a step between cut side surfaces may be reduced, and thus a defect caused by non-peeling of carrier films may be reduced.

Although embodiments of the present disclosure have been described, it is understood that the present disclosure should not be limited to the described embodiments but various changes and modifications can be made by one ordinary skilled in the art within the spirit and scope of the present disclosure.

Therefore, the technical scope of embodiments of the present disclosure is not limited to the described embodiments.

What is claimed is:

1. A method of manufacturing a display device, the method comprising:
preparing a preliminary foldable module including a window module, a display panel disposed on the window module, a panel protective layer disposed on the display panel, and a support plate disposed on the panel protective layer;
performing a first cutting operation, the first cutting operation including cutting the support plate with a first laser beam;
detecting, by a laser-sensing part, reflected light that is reflected from a surface of the panel protective layer exposed by cutting the support plate, and changing the first laser beam to a second laser beam; and
performing a second cutting operation of sequentially cutting the panel protective layer, the display panel, and the window module with the second laser beam.

2. The method of claim 1, wherein:
the first laser beam and the second laser beam are output from a same laser apparatus, and the first and second laser beams differ from each other only based on laser beam conditions; and
the preliminary foldable module is substantially integrally cut.

3. The method of claim 1, wherein the first cutting operation and the second cutting operation are performed in one cutting stage.

4. The method of claim 1, wherein:
the reflected light is not detected by the laser-sensing part in the first cutting operation; and
the reflected light is detected by the laser-sensing part in the second cutting operation.

5. The method of claim 1, wherein an intensity of the first laser beam is greater than an intensity of the second laser beam.

6. The method of claim 1, wherein:
The first laser beam has an output power in a range of about 20 W to about 50 W; and
the second laser beam has an output power in a range of about 1 W to about 20 W.

7. The method of claim 1, wherein the first laser beam and the second laser beam are each emitted from the support plate towards the panel protective layer.

8. The method of claim 1, wherein the support plate comprises a carbon fiber reinforced plastic, a glass fiber reinforced plastic, or a carbon-glass hybrid fiber reinforced plastic.

9. The method of claim 1, wherein:
the window module comprises a window protective layer; and
in the first cutting operation and the second cutting operation, the support plate, the panel protective layer, the display panel, and the window protective layer are cut to form cut side surfaces, the cut side surfaces each have a step less than or equal to about 100 μm.

10. The method of claim 1, wherein:
the preliminary foldable module further comprises at least one adhesive layer; and
the at least one adhesive layer is cut by the second laser beam in the second cutting operation.

11. A method of manufacturing a display device, the method comprising:
preparing a preliminary foldable module including a first group including a support plate and a second group including a display panel, the first group is disposed on the second group;
performing a first cutting operation, the first cutting operation including cutting the first group with a first laser beam;
detecting, by a laser-sensing part, reflected light that is reflected from a surface of the second group exposed by cutting the first group, and changing the first laser beam to a second laser beam; and
performing a second cutting operation of cutting the second group with the second laser beam;
wherein the support plate includes a carbon fiber reinforced plastic, a glass fiber reinforced plastic, or a carbon-glass hybrid fiber reinforced plastic.

12. The method of claim 11, wherein the second group further comprises:
a window module disposed under the display panel; and
a panel protective layer disposed above the display panel.

13. The method of claim 11, wherein:
the support plate does not reflect the first laser beam; and
the second group reflects the first laser beam and the second laser beam.

14. The method of claim 11, wherein:
the first laser beam and the second laser beam are output from a same laser apparatus, and the first and second laser beams differ from each other only based on laser beam conditions; and
the preliminary foldable module is substantially integrally cut.

15. The method of claim 11, wherein the first cutting operation and the second cutting operation are performed in one cutting stage.

16. The method of claim 11, wherein an intensity of the first laser beam is greater than an intensity of the second laser beam.

17. The method of claim 12, wherein the first laser beam and the second laser beam are each emitted from the support plate towards the panel protective layer.

18. The method of claim 11, wherein:
the second group further comprises at least one adhesive layer; and
the at least one adhesive layer is cut by the second laser beam in the second cutting operation.

19. A display device comprising:
a support plate;
a panel protective layer disposed on the support plate;
a display panel disposed on the panel protective layer; and
a window module including a window protective layer, the window module is disposed on the display panel,
wherein the support plate includes a carbon fiber reinforced plastic, a glass fiber reinforced plastic, or a carbon-glass hybrid fiber reinforced plastic, and
a side surface of each of the support plate, the panel protective layer, the display panel, and the window protective layer has a step less than or equal to about 100 μm.

20. The display device of claim 19, further comprising a digitizer disposed below the support plate.
